(19) United States
(12) Patent Application Publication
(10) Pub. No.: US 2014/0231876 A1
(43) Pub. Date: Aug. 21, 2014

(54) pHEMT and HBT integrated epitaxial structure

(71) Applicant: WIN Semiconductors Corp., Tao Yuan Shien (TW)

(72) Inventors: Shu-Hsiao TSAI, Tao Yuan Shien (TW); Cheng-Kuo LIN, Tao Yuan Shien (TW); Bing-Shan HONG, Tao Yuan Shien (TW); Shinichiro Takatani, Tao Yuan Shien (TW)

(73) Assignee: WIN Semiconductors Corp., Tao Yuan Shien (TW)

(21) Appl. No.: 14/264,721

(22) Filed: Apr. 29, 2014

Related U.S. Application Data
(63) Continuation-in-part of application No. 13/662,162, filed on Oct. 26, 2012.

(30) Foreign Application Priority Data
Jun. 1, 2012 (TW) 101119726

(51) Int. Cl. H01L 29/778; H01L 27/06

(52) U.S. Cl. CPC H01L 29/7782; H01L 27/0623
USPC 257/195; 257/194

(57) ABSTRACT

An improved pseudomorphic high electron mobility transistor (pHEMT) and heterojunction bipolar transistor (HBT) integrated epitaxial structure, in which the structure comprises a substrate, a pHEMT structure, an etching-stop spacer layer, and an HBT structure. The pHEMT structure comprises a buffer layer, a bottom barrier layer, a first channel spacer layer, a channel layer, a second channel spacer layer, a Schottky spacer layer, a Schottky donor layer, a Schottky barrier layer, an etching-stop layer, and at least one cap layer. By introducing the first channel spacer layer and the second channel spacer layer to reduce the density of the dislocations and to reduce the compressive strain in the pseudomorphic channel layer.

### CROSS-REFERENCE TO RELATED APPLICATIONS

This application is a Continuation-in-Part of co-pending application Ser. No. 13/662,162, filed on Oct. 26, 2012, for which priority is claimed under 35 U.S.C. §120; and this application claims priority of Application No. 101119726 filed in Taiwan, R.O.C. on Jun. 1, 2012 under 35 U.S.C. §119, the entire contents of all of which are hereby incorporated by reference.

### FIELD OF THE INVENTION

The present invention relates to an improved pseudomorphic high electron mobility transistor (pHEMT) and heterojunction bipolar transistor (HBT) integrated epitaxial structure, in particular to an improved pHEMT and HBT integrated epitaxial structure, in which a first and a second channel spacer layers are included above and below a channel layer respectively.

### BACKGROUND OF THE INVENTION

Pseudomorphic high electron mobility transistor (pHEMT) and heterojunction bipolar transistor (HBT) have the advantage of high efficiency, high linearity, high power density, and small size. They are important devices commonly used as microwave power amplifiers in wireless communications. Integrating the two devices in the same chip will not only lower the manufacturing cost, but also reduce necessary space for device assembling, which hence leads to reduction of the chip size.

FIG. 1 is a schematic showing the cross-sectional view for a conventional pHEMT and HBT integrated epitaxial structure. The structure comprises sequentially a substrate 101, a pHEMT structure 170, an etching-stop spacer layer 119, and an HBT structure 180. The pHEMT structure 170 comprises a buffer layer 103, a first δ-doped layer (planar doping sheet layer) 105, a barrier layer 107, a channel layer 109, a Schottky barrier layer 111, a second δ-doped layer 113, an etching-stop layer 115, and a contact layer 117, in which the buffer layer 103 is formed on the substrate 101; the first δ-doped layer 105 is formed on the buffer layer 103; the barrier layer 107 is formed on the first δ-doped layer 105; the channel layer 109 is formed on the barrier layer 107; the Schottky barrier layer 111 is formed on the channel layer 109; the second δ-doped layer 113 is formed on the Schottky barrier layer 111; the etching-stop layer 115 is formed on the second δ-doped layer 113; and the contact layer 117 is formed on etching-stop layer 115. The HBT structure 180 comprises a collector layer 121, a base layer 123, an emitter layer 125, an emitter contact layer 127, in which the collector layer 121 is formed on etching-stop spacer layer 119; the base layer 123 is formed on the collector layer 121; the emitter layer 125 is formed on the base layer 123; and the emitter contact layer 127 is formed on the emitter layer 125. The epitaxial structure provided by the conventional technology can be used to form pHEMT and HBT accordingly. In the conventional pHEMT structure 170, twos-doped layers are employed. The twos-doped layers are for the improvement of higher current injection which can increasing the current density and reduce the resistance of a pHEMT. However, highly integrated technology, smaller die size, and better performance is highly required in the future commercial radio frequency communication modules.

In view of these facts and for achieving the improvements stated above, the present invention provides an improved pHEMT and HBT integrated epitaxial structure. The device and the fabrication method according to the present invention can lower the resistance of pHEMT more effectively. When employed as switch elements, it can provide the switch with low insertion loss and reduce the device size. Furthermore, the fabrication process for the device can provide a high stability and reliability.

### SUMMARY OF THE INVENTION

Due to the lattice constants mismatch between InGaAs and AlGaAs (or GaAs), the crystal defects would be presented on the interface of the heterojunction when growing InGaAs on AlGaAs (or GaAs) by the lattice strain. A pHEMT structure is to grow a thin strained pseudomorphic InGaAs channel layer with moderate Indium content on the AlGaAs (or GaAs) layer. The conventional and typical channel layer of pHEMT has an Indium content of 20% and a thickness of 12 nm. In order to obtain higher electron mobility in the channel for lowering the resistance, a higher Indium content channel is needed. However, higher Indium content will generate higher lattice strain and induce more lattice dislocations and defects. The lattice dislocations and defects as the traps of electrons will decrease the current density and minimize the advantage of increasing higher Indium content of InGaAs channel layer, or even degrade its original performance.

In order to enhance the pHEMT performance which can introduce lower insertion loss and higher power handling by increasing the content of Indium in the pseudomorphic channel layer but also minimize the lattice dislocations and defects by strain, the present invention disclosed an improved channel layer structure by introducing two channel spacer layers to release the compressive strain in the pseudomorphic channel layer with higher Indium content and further reduce the density of the dislocations.

The main object of the present invention is to provide an improved pseudomorphic high electron mobility transistor (pHEMT) and heterojunction bipolar transistor (HBT) integrated epitaxial structure, in which a first channel spacer layer and a second channel spacer layer are included above and below a channel layer respectively. By changing the thickness of the channel layer, the first channel spacer layer, and the second channel spacer layer of the structure, a transistor structure with required characteristics properties can be provided. In the channel layer, compound semiconductor alloy InₓGa₁₋ₓAs is used. By raising the Indium content x in InₓGa₁₋ₓAs, the resistance can be lowered. By using GaAs in the first channel spacer layer and the second channel spacer layer, the electric field of the gate can be dispersed, and then the on-resistance can be lowered. When used in a switching device, the structure can provide the device with the advantage of the low insertion loss, the reduced device size, the stable fabrication process and high device reliability.

To reach the objects stated above, the present invention provides an improved pHEMT structure, which comprises from bottom to top sequentially a substrate, a buffer layer, a bottom barrier layer, a first channel spacer layer, a channel layer, a second channel spacer layer, a Schottky spacer layer, a Schottky donor layer, a Schottky barrier layer, an etching-stop layer, at least one cap layer, a gate recess formed by using at least one etching process terminated at the Schottky barrier layer, a gate electrode disposed in the gate recess on the Schottky barrier layer, a drain electrode disposed on one end of the cap layer, and a source electrode disposed on the other end of the cap layer; wherein the channel layer is composed of InₓGa₁₋ₓAs compound semiconductor with the In content 0.2<x<0.5.

In an embodiment, the bottom barrier layer comprises: a barrier layer formed on the buffer layer; a barrier donor layer formed on the barrier layer; and a barrier spacer layer formed on the barrier donor layer, wherein the first channel spacer layer is formed on the barrier spacer layer.

In an embodiment, the barrier layer, the barrier donor layer and the barrier spacer layer are composed of AlGaAs or GaAs.

In an embodiment, the barrier donor layer and the Schottky donor layer are composed of a Si delta-doping.

In an embodiment, the thickness of the channel layer is between 10 Å and 300 Å.

In an embodiment, the first channel spacer layer and the second channel spacer layer are composed of GaAs.

In an embodiment, the thickness of the first channel spacer layer and the thickness of the second channel spacer layer is between 10 Å and 200 Å.

In an embodiment, the Schottky barrier layer, the Schottky donor layer and the Schottky spacer layer are composed of AlGaAs.

In an embodiment, at least one upper stacked cap layer is disposed on the cap layer; the at least one upper stacked cap layer is positioned between the cap layer and the drain electrode and the at least one upper stacked cap layer is positioned between the cap layer and the source electrode; the at least one upper stacked cap layer includes at least one stacked cap layer.

In an embodiment, a stacked etching-stop layer is further included in the upper stacked cap layer below the stacked cap layer, so that the upper stacked cap layer includes: the stacked etching-stop layer; and the stacked cap layer disposed on the stacked etching-stop layer.

In an embodiment, the drain electrode may be deposited on one end of the cap layer and forms an ohmic contact to the cap layer, and the source electrode may be deposited on another end of the cap layer and forms an ohmic contact to the cap layer.

The present invention also provides an improved pHEMT and HBT integrated epitaxial structure, which comprises from bottom to top sequentially a substrate, a pHEMT structure, an etching-stop spacer layer, and an HBT structure. The pHEMT structure comprises from bottom to top sequentially a buffer layer, a bottom barrier layer, a first channel spacer layer, a channel layer, a second channel spacer layer, a Schottky spacer layer, a Schottky donor layer, a Schottky barrier layer, an etching-stop layer, and at least one cap layer. The HBT structure comprises from bottom to top sequentially a sub-collector layer, a collector layer, a base layer, an emitter layer, and an emitter cap layer; wherein the channel layer is composed of InₓGa₁₋ₓAs compound semiconductor with the In content 0.2<x<0.5.

In another embodiment, the bottom barrier layer comprise: a barrier layer formed on the buffer layer; a barrier donor layer formed on the barrier layer; and a barrier spacer layer formed on the barrier donor layer, wherein the first channel spacer layer is formed on the barrier spacer layer.

In another embodiment, said barrier layer, barrier donor layer and said barrier spacer layer are composed of AlGaAs or GaAs.

In another embodiment, said barrier donor layer and said Schottky donor layer are composed of a Si delta-doping.

In another embodiment, the thickness of said channel layer is between 10 Å and 300 Å.

In another embodiment, said first channel spacer layer and said second channel spacer layer are formed of GaAs.

In another embodiment, the thickness of said first channel spacer layer and the thickness of said second channel spacer layer are between 10 Å and 200 Å.

In another embodiment, said Schottky barrier layer, said Schottky donor layer and said Schottky spacer layer are composed of AlGaAs.

In an embodiment, at least one upper stacked cap layer is disposed on the cap layer, and the at least one upper stacked cap layer includes at least one stacked cap layer.

In another embodiment, a stacked etching-stop layer is further included in the upper stacked cap layer below the stacked cap layer, so that the upper stacked cap layer includes: the stacked etching-stop layer; and the stacked cap layer disposed on the stacked etching-stop layer.

In another embodiment, the drain electrode may be deposited on one end of the cap layer and forms an ohmic contact to the cap layer, and the source electrode may be deposited on another end of the cap layer and forms an ohmic contact to the cap layer.

In another embodiment, an emitter contact layer is further included on said emitter cap layer.

In another embodiment, an ohmic contact can be formed between the emitter electrode and the emitter cap layer.

In another embodiment, an emitter contact layer can be further included between the emitter electrode and the emitter cap layer in the structure and method stated above, and an ohmic contact can be formed between the emitter electrode and the emitter contact layer. At least one etching process of the emitter contact layer is then included in the etching process of the base electrode contact region.

For further understanding the characteristics and effects of the present invention, some preferred embodiments referred to drawings are in detail described as follows.

### BRIEF DESCRIPTION OF DRAWINGS

FIG. 1 is a schematic showing the cross-sectional view of a conventional pHEMT and HBT epitaxial structure.

FIG. 1A is the comparison of the transfer curves of the performance of the conventional pHEMT and the pHEMT of the present invention.

FIG. 1B is the comparison of the I-V curves of the performance under VGS at −1.0V, −0.5V, 0.0V, 0.5V and 1.0V of the conventional pHEMT and the pHEMT of the present invention.

FIG. 2-4 are the sectional views of the embodiments of the improved pHEMT epitaxial structure in the present invention.

FIG. 5-10 are the sectional views of the embodiments of the improved pHEMT and HBT epitaxial structure in the present invention.

### DETAILED DESCRIPTIONS OF PREFERRED EMBODIMENTS

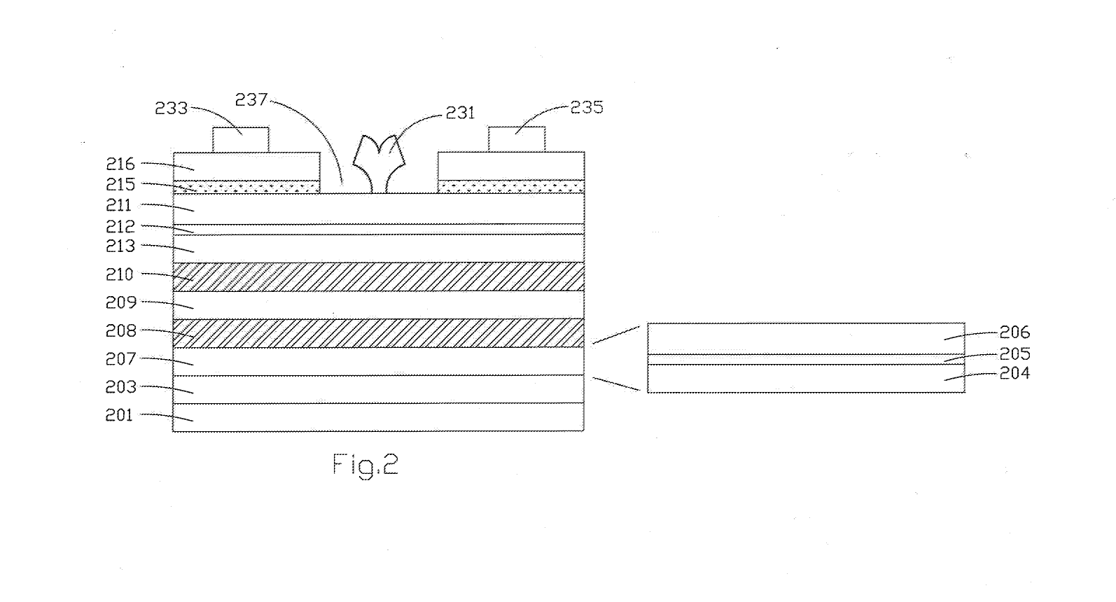

FIG. 2 is a sectional view of an embodiment of the improved pHEMT epitaxial structure in the present invention, which comprises a substrate 201, a buffer layer 203, a bottom barrier layer 207, a first channel spacer layer 208, a channel layer 209, a second channel spacer layer 210, a Schottky spacer layer 213, a Schottky donor layer 212, a Schottky barrier layer 211, an etching-stop layer 215, at least one cap layer 216, a gate electrode 231, a drain electrode 233, a source electrode 235, and a gate recess 237.

The substrate 201 is preferably a semi-insulating GaAs substrate. The buffer layer 203 is formed on the substrate 201. The buffer layer 203 can be made of AlGaAs or GaAs, and preferably a combination of an undoped AlGaAs layer and an undoped GaAs layer. The bottom barrier layer 207 is formed on the buffer layer 203. The bottom barrier layer 207 can be made of AlGaAs, and preferably a combination of plural undoped AlGaAs layers and n-type doped AlGaAs layers. The first channel spacer layer 208 is formed on the barrier layer 207. The first channel spacer layer 208 can be made of GaAs, and preferably an undoped GaAs, and the thickness of the first channel spacer layer 208 is usually between 10 Å and 200 Å, preferably between 20 Å and 70 Å. The channel layer 209 is formed on the first channel spacer layer 208. The channel layer 209 is made preferably of InₓGa₁₋ₓAs with the Indium content 0.2<x<0.5, more preferably with the Indium content 0.3<x<0.4, and the thickness of the channel layer 209 is usually between 10 Å and 300 Å. The second channel spacer layer 210 is formed on the channel layer 209. The second channel spacer layer 210 can be made of GaAs, and preferably an undoped GaAs, and the thickness of the first channel spacer layer 208 is usually between 10 Å and 200 Å, preferably between 20 Å and 70 Å. The Schottky spacer layer 213 is formed on the second channel spacer layer 210. The Schottky spacer layer 213 may be made of AlGaAs, and preferably undoped AlGaAs or n-type doped AlGaAs. The Schottky donor layer 212 is formed on the Schottky spacer layer 213. The Schottky donor layer 212 may be made of AlGaAs, and preferably undoped AlGaAs or n-type doped AlGaAs. In an embodiment, the Schottky donor layer 212 may be represented by a Si delta-doping. The Schottky barrier layer 211 is formed on the Schottky donor layer 212. The Schottky barrier layer 211 can be made of AlGaAs, and preferably undoped AlGaAs or n-type doped AlGaAs. The etching-stop layer 215 is formed on the Schottky barrier layer 211, and it is made preferably of AlAs or InGaP. The cap layer 216 is formed on the etching-stop layer 215. The cap layer 216 can be made of GaAs, AlₓGa₁₋ₓAs, InₓAl₁₋ₓAs, InₓGa₁₋ₓAs, or InAlGaAs, and preferably a combination of plural layers made of the materials described previously. A gate recess 237 is formed by first defining the position and area of a gate recess region using photolithography, and then by etching the cap layer 216 and terminating the etching process at the etching-stop layer 215. The etching process can either be a wet etching or a dry etching, as long as the etching selectivity is good. In wet etching, for example, if the cap layer 216 is made of GaAs, the suitable etchants can be citric acid, succinic acid, or acetic acid. The gate recess 237 is finally formed by etching the etching-stop layer 215 and terminating the etching process at the Schottky barrier layer 211. The etching process can either be a wet etching or a dry etching as well, as long as the etching selectivity is good. In wet etching, for example, NH₄OH, H₂O₂, or HCl solution are suitable etchants for AlAs, and HCl solution is suitable etchant for InGaP. A gate electrode 231 is deposited in the gate recess 237 on the Schottky barrier layer 211, and an ohmic contact is formed between the gate electrode 237 and said Schottky barrier layer 211. A drain electrode 233 is deposited on one end of the cap layer 216, and an ohmic contact is formed between the drain electrode 233 and the cap layer 216. A source electrode 235 is deposited on another end of the cap layer 216, and an ohmic contact is formed between the source electrode 235 and the cap layer 216.

In some embodiments, the Schottky spacer layer 213, the Schottky donor layer 212 and the Schottky barrier are made of the same compound material, such as AlGaAs. For example, the Schottky spacer layer 213 may be made of an undoped AlGaAs, while the Schottky donor layer 212 and the Schottky barrier layer 211 may be made of an n-type doped AlGaAs.

In an embodiment, the bottom barrier 207 comprises: a barrier layer 204, a barrier donor layer 205 and a barrier spacer layer 206. The barrier layer 204 is formed on the buffer layer 203. The barrier layer 204 may be made of AlGaAs or GaAs, and preferably undoped AlGaAs, n-type doped AlGaAs, undoped GaAs or n-type doped GaAs. The barrier donor layer 205 is formed on the barrier layer 204. The barrier donor layer 205 may be made of AlGaAs or GaAs, and preferably undoped AlGaAs, n-type doped AlGaAs, undoped GaAs or n-type doped GaAs. In an embodiment, the barrier donor layer 205 may be represented by a Si delta-doping. The barrier spacer layer 206 is formed on the barrier donor layer 205. The barrier spacer layer 206 may be made of AlGaAs or GaAs, and preferably undoped AlGaAs, n-type doped AlGaAs, undoped GaAs or n-type doped GaAs.

In some embodiments, the barrier layer 204, the barrier donor layer 205 and the barrier spacer layer 206 are made of the same compound material. For example, the barrier layer 204 and the barrier spacer layer 206 may be made of an undoped AlGaAs, while the barrier donor layer 205 may be made of an n-type doped AlGaAs. In other some embodiments, the barrier layer 204 and the barrier spacer layer 206 may be made of an undoped GaAs, while the barrier donor layer 205 may be made of an n-type doped GaAs.

There are two kinds of spacer layers above the channel layer 209. One is the second channel spacer layer 210, which is related to the channel layer 209. The other is the Schottky spacer layer 213, which is related to the Schottky barrier layer 211. The function of the Schottky spacer layer 213 is to increase the electron mobility by separating the confined 2 dimensional electron gas in the InGaAs channel layer 209 from ionized donors generated by the Schottky donor layer 212, while the function of the second channel spacer layer 210 is to reduce the density of the dislocations and to reduce the compressive strain due to the highly mismatch between the AlGaAs Schottky spacer layer 213 and the InGaAs channel layer 209. The Schottky spacer layer 213 is usually a thin layer of undoped compound material, which is usually the same compound material as the Schottky barrier layer 211, while the thickness of the second channel spacer layer 210 is usually related to the Indium content x of InGaAs of the channel layer 209. When the Indium content x is larger, a thicker of thickness of the second channel spacer layer 210 is needed, and when the Indium content x is smaller, a thinner of thickness of the second channel spacer layer 210 is needed.

In some embodiments, the bottom barrier layer 207 comprises the barrier layer 204, the barrier donor layer 205 and the barrier spacer layer 206. Similarly, there are two kinds of spacer layers below the channel layer 209. One is the first channel spacer layer 208, which is related to the channel layer 209. The other is the barrier spacer layer 206, which is related to the barrier layer 204. The function of the barrier spacer layer 206 is different from the first channel spacer layer 208. The function of the first channel spacer layer 208 is to reduce the density of the dislocations and to reduce the compressive strain due to the highly mismatch between the barrier spacer layer 206 and the InGaAs channel layer 209. The barrier spacer layer 206 is usually a thin layer of undoped compound material, which is usually the same compound material as the barrier layer 204, while the thickness of the first channel spacer layer 208 is usually related to the Indium content x of InGaAs of the channel layer 209. When the Indium content x is larger, a thicker of thickness of the first channel spacer layer 208 is needed, and when the Indium content x is smaller, a thinner of thickness of the first channel spacer layer 208 is needed.

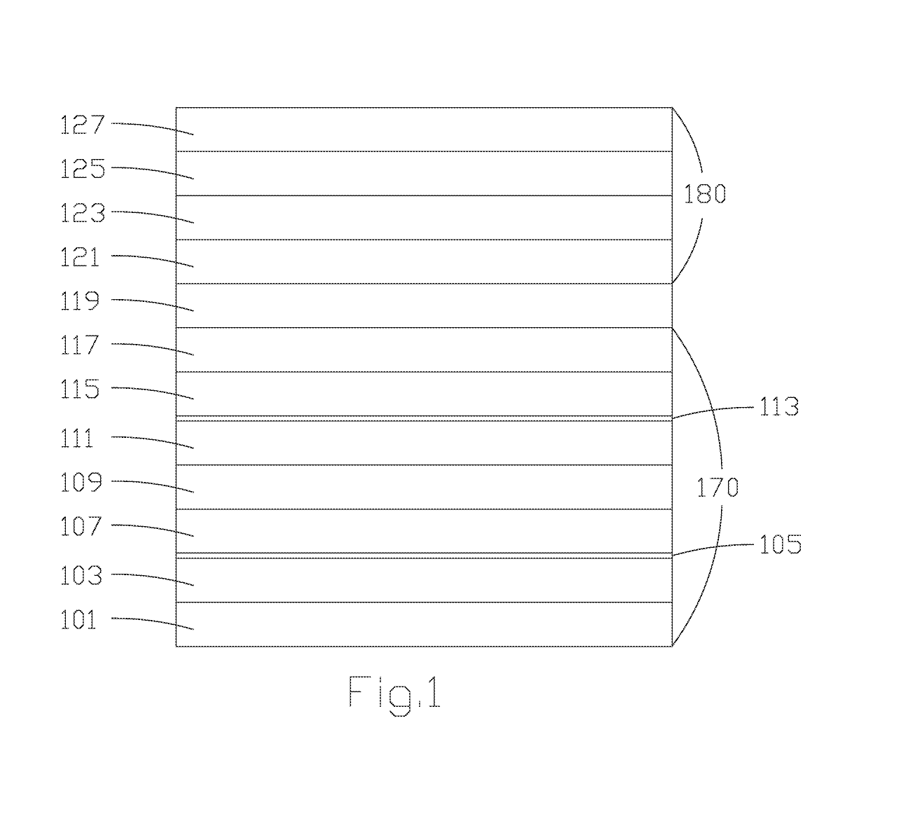

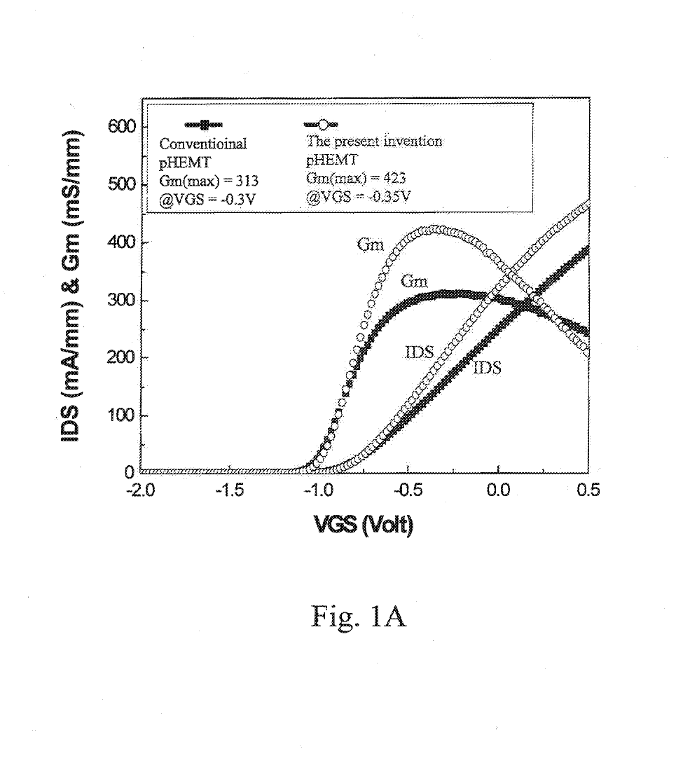

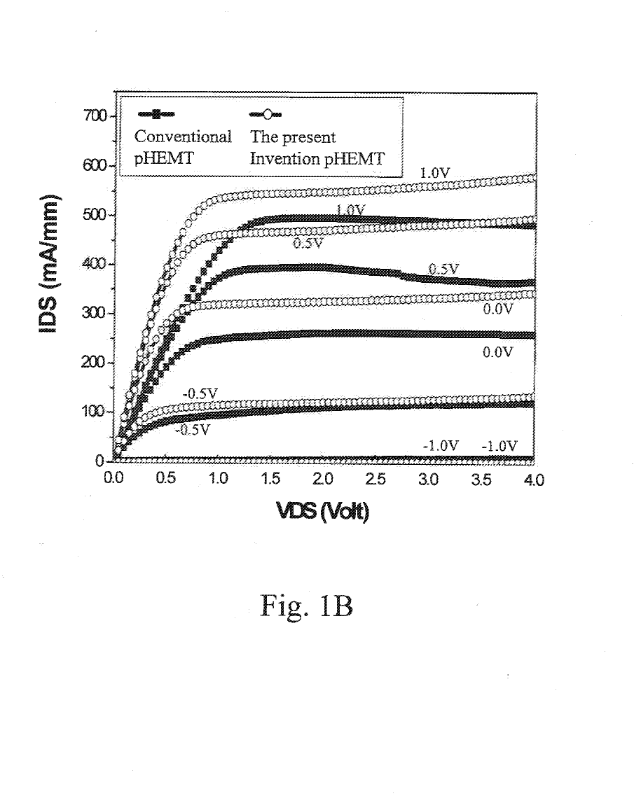

Please refer to FIG. 1A, which are the transfer curves and shows the comparison of the performance of the conventional pHEMT and the pHEMT of the present invention. The conventional pHEMT is mostly same to the pHEMT of the present invention, except the conventional pHEMT doesn't include the first channel spacer layer 208 and the second channel spacer layer 210. In FIG. 1A, the x axis is the voltage between the gate and the source (VGS). The unit of x axis is Volt. The IDS curves represent the drain current when applying VGS. The unit of IDS is mA/mm. The pinch-off voltage is −1.0V. Hence, when the applying VGS is below −1.0V, the drain current is nearly zero. By increasing the applying VGS, the drain current is increasing. Comparing the IDS curves, when VGS is higher than −1.0V, the IDS value of the IDS curve of the present invention pHEMT is larger than the IDS value of the IDS curve of the conventional pHEMT. That means the present invention pHEMT has a lower on-resistance and a higher drain current.

The Gm curves represent the transconductance. The unit of Gm is ms/mm. The present invention pHEMT shows higher peak Gm than the conventional pHEMT which the peak Gm of the present invention pHEMT and conventional pHEMT are 423 and 313 respectively. That is, the maximum gain of the present invention pHEMT is 1.35 times of the gain of the conventional pHEMT.

Please refer to FIG. 1B, which shows the comparison of I-V curves of the conventional pHEMT and the pHEMT of the present invention under VGS at −1.0V, −0.5V, 0.0V, 0.5V and 1.0V.

The x axis is the voltage between the drain and the source (VDS). The unit of x axis is Volt. The y axis is the drain current IDS. The unit of IDS is mA/mm. The pinch-off voltage is −1.0V. Hence, when the applying VGS is −1.0V, the drain current is nearly zero. By increasing the applying VGS, the drain current is increasing. Before IDS getting saturated, the slope represented the on resistance. The curves of the present invention pHEMT is always greater than the slope of the curves of the conventional pHEMT which means the on-resistance of the present invention pHEMT is lower than the on-resistance of the conventional pHEMT no matter the applying VGS is −0.5V, 0.0V, 0.5V or 1.0V.

After the comparison of the performance of the present invention pHEMT and the conventional pHEMT, it is no doubt that the performance of the present invention pHEMT is much more excellent than the conventional pHEMT.

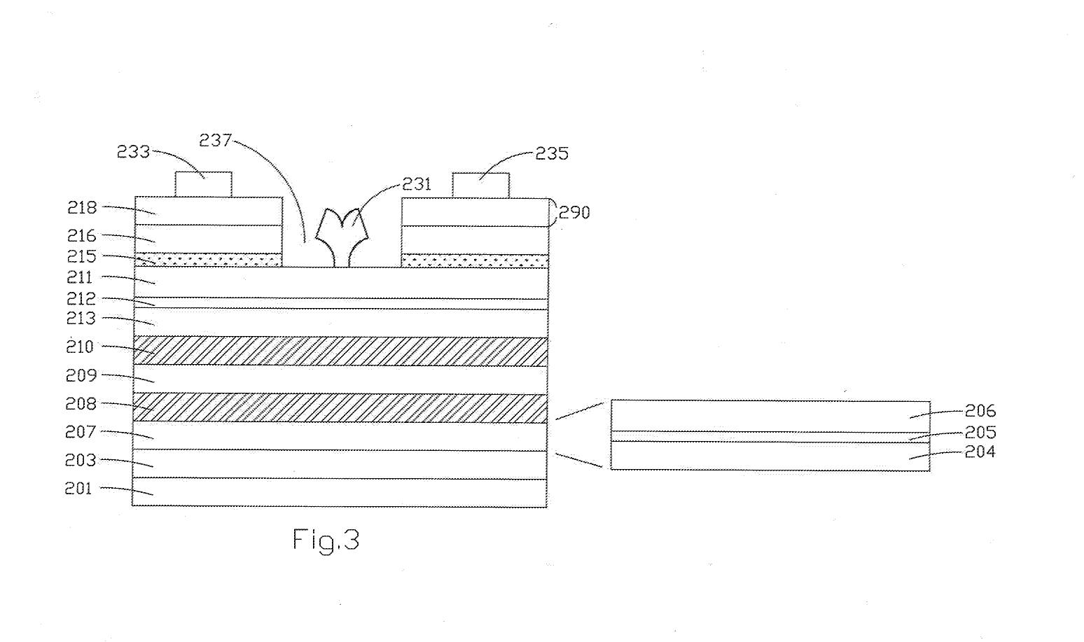

FIG. 3 is a sectional view of an embodiment of the improved pHEMT epitaxial structure in the present invention. The structure is mostly same to the embodiment shown in FIG. 2, except that at least one upper stacked cap layer 290 is disposed on the cap layer 216 positioning between the cap layer 216 and the drain electrode 233 and between the cap layer 216 and the source electrode 235. The upper stacked cap layer 290 includes at least one stacked cap layer 218, which can be made of GaAs, AlₓGa₁₋ₓAs, InAl₁₋ₓAs, InₓGa₁₋ₓAs, or InAlGaAs, and preferably a combination of plural layers made of the materials described previously. The etching process before etching the cap layer 216 further includes etching the upper stacked cap layer 290 and terminating the etching process at the cap layer 216. Then the cap layer 216 is etched. The etching process can be either a wet etching or a dry etching, as long as the etching selectivity is good. In wet etching, for example, if the stacked cap layer of the upper stacked cap layer 290 is made of GaAs, the suitable etchants can be citric acid, succinic acid, or acetic acid. A drain electrode 233 is deposited on one end of the upper stacked cap layer 290, and an ohmic contact between the drain electrode 233 and the upper stacked cap layer 290 is formed. A source electrode 235 is deposited on another end of the upper stacked cap layer 290, and an ohmic contact between the source electrode 235 and the upper stacked cap layer 290 is formed.

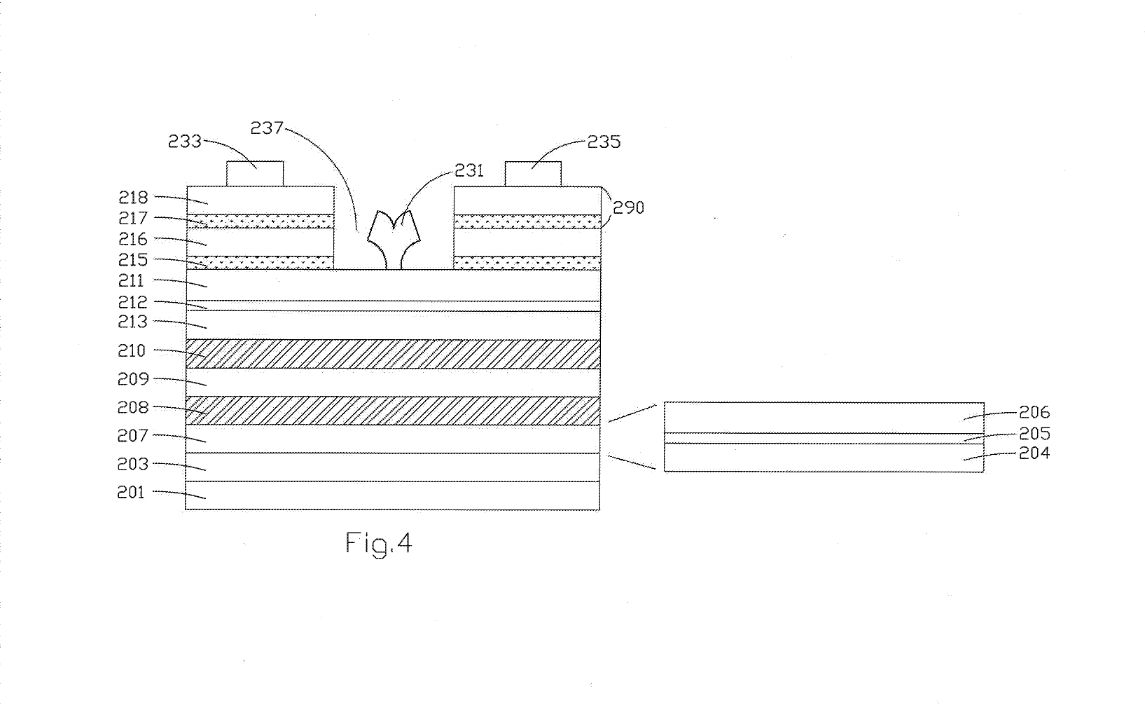

FIG. 4 is a sectional view of an embodiment of the improved pHEMT epitaxial structure in the present invention. The structure is mostly same to the embodiment shown in FIG. 3, except that a stacked etching-stop layer 217 is disposed in the structure of the upper stacked layer 290 below the stacked cap layer 218. The stacked etching-stop layer 217 is made preferably of AlAs or InGaP. An additional etching process of the stacked etching-stop layer 217 has to be included in the etching process of the upper stacked layer 290. The etching process can be either a wet etching or a dry etching, as long as the etching selectivity is good. In wet etching, for example, NH₄OH, H₂O₂, or HCl solution are suitable etchants for AlAs, and HCl solution is suitable etchant for InGaP.

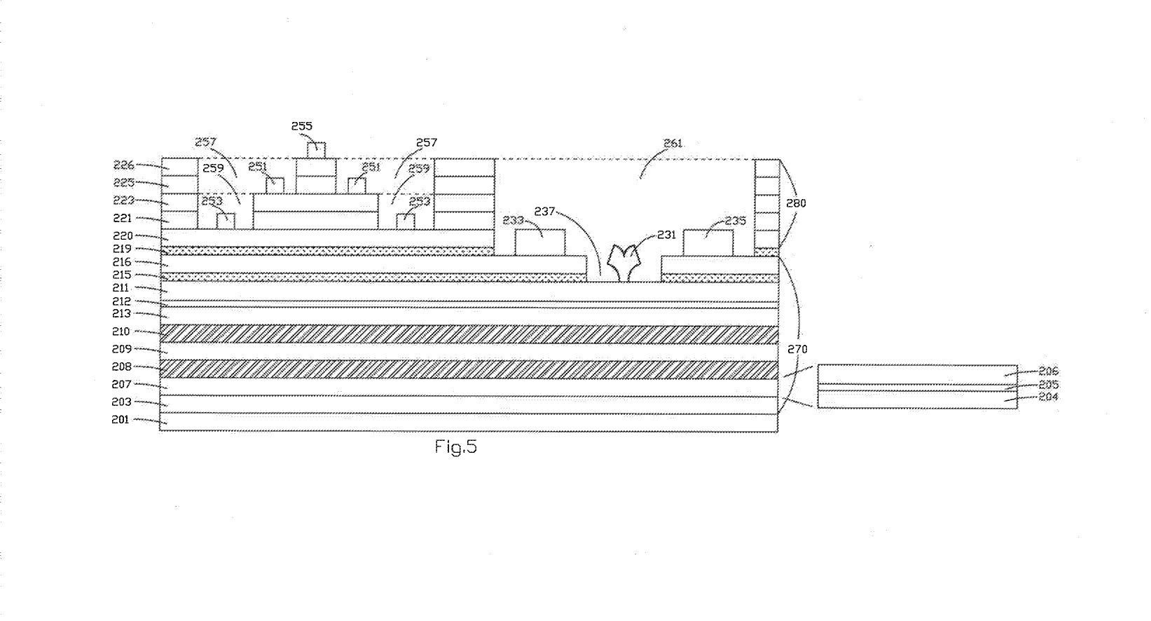

FIG. 5 is a sectional view of an embodiment of the improved pHEMT and HBT epitaxial structure in the present invention. The structure comprises a substrate 201, a pHEMT structure 270, an etching-stop spacer layer 219, and an HBT structure 280. The fabrication steps of an HBT and a pHEMT are also included. The pHEMT structure 270 is mostly same to the structure shown in FIG. 2, which comprises a buffer layer 203, a bottom barrier layer 207, a first channel spacer layer 208, a channel layer 209, a second channel spacer layer 210, a Schottky spacer layer 213, a Schottky donor layer 212, a Schottky barrier layer 211, an etching-stop layer 215, and at least one cap layer 216. In an embodiment, the bottom barrier 207 comprises: a barrier layer 204, a barrier donor layer 205 and a barrier spacer layer 206. The barrier layer 204 is formed on the buffer layer 203. The barrier donor layer 205 is formed on the barrier layer 204. The barrier spacer layer 206 is formed on the barrier donor layer 205. The etching-stop spacer layer 219 is formed on the pHEMT structure 270, and it is formed preferably of AlAs or InGaP. The HBT structure 280 comprises a sub-collector layer 220, a collector layer 221, a base layer 223, an emitter layer 225, and an emitter cap layer 226. The sub-collector layer 220 is formed on the etching-stop layer 219, and it is made preferably of undoped GaAs or n+ type Si doped GaAs. The collector layer 221 is formed on the sub-collector layer 220, and it is made preferably of n-type doped GaAs with the preferable doping Si or similar materials. The base layer 223 is formed on the collector layer 221, and it is made preferably of p-type doped GaAs with the preferable doping carbon or similar materials. The emitter layer 225 is formed on the base layer 223, and it is made preferably of n-type doped InGaP with the preferable doping Si or similar materials. The emitter cap layer 226 is formed on the emitter layer 225, and it is made preferably of n-type doped GaAs with the preferable doping Si or similar materials. The fabrication steps for the HBT includes: Defining a base electrode contact region 257 by photolithography; first etching the emitter cap layer 226 in the base electrode contact region 257 and terminating the etching process at the emitter layer 225, in which the etching process can be either a wet etching or a dry etching, as long as the etching selectivity is good. In wet etching, for example, the suitable etchants for GaAs can be citric acid, succinic acid, or acetic acid; Etching the emitter layer 225 in the base electrode contact region 257 and terminating the etching process at the base layer 223, in which the etching process can be either a wet etching or a dry etching as well, as long as the etching selectivity is good; Defining a collector electrode contact region 259 on the base electrode contact region 257 by photolithography, and then etching the base layer 223 in the collector electrode contact region 259 and terminating the etching process at the collector layer 221, in which the etching process can be either a wet etching or a dry etching, as long as the etching selectivity is good. In wet etching, for example, the suitable etchants for GaAs can be citric acid, succinic acid, or acetic acid; Etching the collector layer 221 in the collector electrode contact region 259 and terminating the etching process at the sub-collector layer 220, in which the etching process can be either a wet etching or a dry etching as well, as long as the etching selectivity is good; Depositing a collector electrode 253 on the sub-collector layer 220 in the collector electrode contact region 259, and forming an ohmic contact between the collector electrode 253 and the sub-collector layer 220; Depositing a base electrode 251 on the base layer 223 in the base electrode contact region 259, and forming an ohmic contact between the base electrode 251 and the base layer 223; Depositing an emitter electrode 255 on one end of the emitter cap layer 226, and forming an ohmic contact between the emitter electrode 255 and the emitter cap layer 226. The fabrication steps for the pHEMT includes: Defining a pHEMT etching region 261 by photolithography; First etching the HBT structure 280 by sequentially etching the emitter cap layer 226, the emitter layer 225, the base layer 223, the collector layer 221, and the sub-collector layer 220, and terminating the etching process at the etch stop spacer layer 219; Etching the etch stop spacer layer 219 and terminating the etching process at the cap layer 216, in which the etching process can be either a wet etching or a dry etching, as long as the etching selectivity is good. In wet etching, for example, NH₄OH, H₂O₂, or HCl solution are suitable etchants for AlAs, and HCl solution is suitable etchant for InGaP; Defining a gate recess region on the pHEMT etching region 261 by photolithography, and then etching the cap layer 216 and terminating the etching process at the etching-stop layer 215; Forming a gate recess by etching the etching-stop layer 215 in the pHEMT etching region 261 and terminating the etching process at the Schottky barrier layer 211; depositing a gate electrode 231 in the gate recess 237 on the Schottky barrier layer 211, and forming an ohmic contact between the gate electrode 231 and the Schottky barrier layer 211; depositing a drain electrode 233 on one end of the cap layer 216 in the pHEMT etching region 261, and forming an ohmic contact between the drain electrode 233 and the cap layer 216; Depositing a source electrode 235 on another end of the cap layer 216 in the pHEMT etching region 261, and forming an ohmic contact between the source electrode 235 and the cap layer 216.

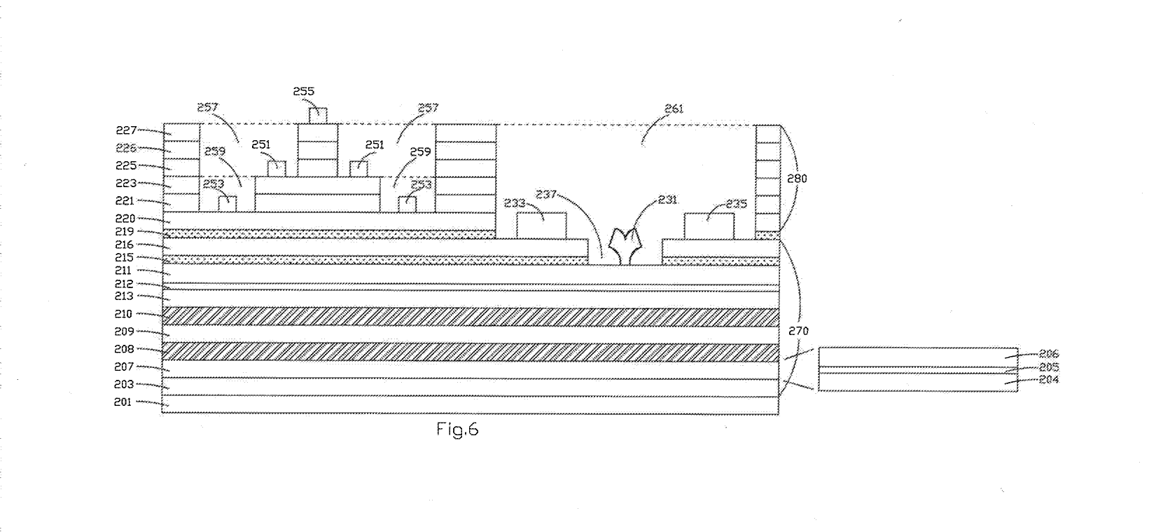

FIG. 6 is a sectional view of an embodiment of the improved pHEMT and HBT epitaxial structure in the present invention. The structure is mostly same to the embodiment shown in FIG. 5, except that an emitter contact layer 227 is further included on the emitter cap layer 226 positioning between the emitter cap layer 226 and the emitter electrode 255. The emitter contact layer 227 is made preferably of n-type doped AlGaAs with the preferable doping Si or similar materials. For the insertion of the emitter contact layer 227, the fabrication steps for the HBT and for the pHEMT should be modified accordingly. An additional step must be included in the fabrication steps of the HBT before etching the emitter cap layer 226 in the base electrode contact region 257, that is, first etching the emitter contact layer 227 in the base electrode contact region 257 and terminating the etching process at the emitter cap layer 226, and then etching the emitter cap layer 226 in the base electrode contact region 257 and forming an ohmic contact between the base electrode 255 and the emitter contact layer 227. An additional step must be included as well in the fabrication steps of the pHEMT before etching the HBT structure 280, that is, first etching the emitter contact layer 227 in the pHEMT etching region 261 and terminating the etching process at the emitter cap layer 226, and then etching the HBT structure 280 in the pHEMT etching region 261 sequentially.

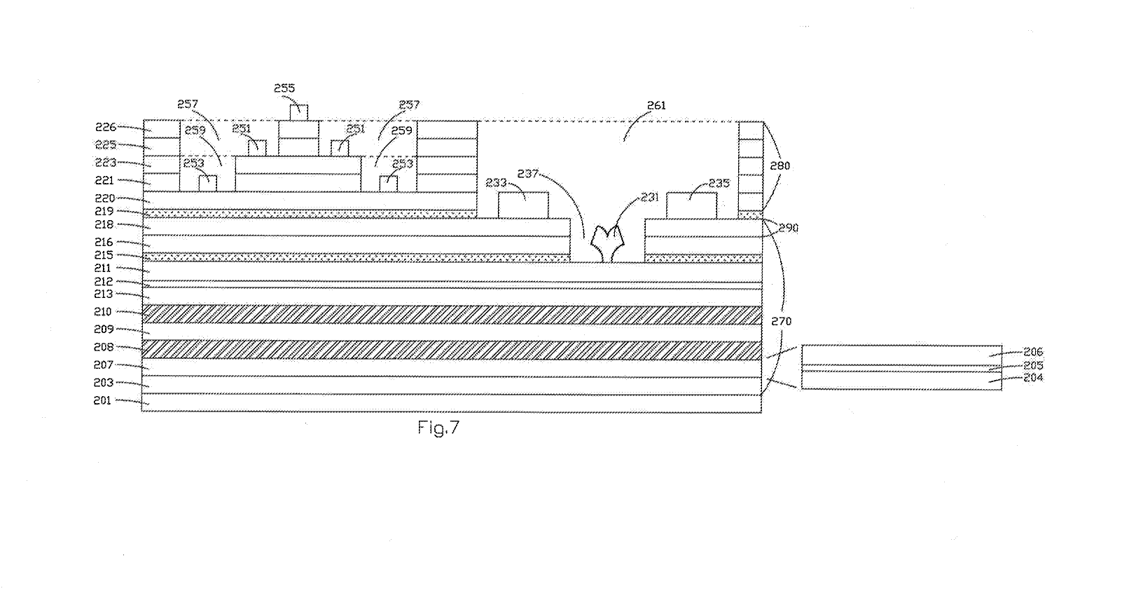

FIG. 7 is a sectional view of an embodiment of the improved pHEMT and HBT epitaxial structure in the present invention. The structure is mostly same to the embodiment shown in FIG. 5, except that at least one upper stacked cap layer 290 is disposed on the cap layer 216 positioning between the cap layer 216 and the drain electrode 233 and between the cap layer 216 and the source electrode 235. The upper stacked cap layer 290 includes at least one stacked cap layer 218. The upper stacked cap layer 290 comprises at least one stacked cap layer, which is made of GaAs, AlₓGa₁₋ₓAs, InₓAl₁₋ₓAs, InₓGa₁₋ₓAs, or InAlGaAs, and preferably a combination of plural layers made of the materials described previously. An additional step must be included in the fabrication steps of the HBT before etching the cap layer 216, that is, first etching the upper stacked cap layer 290 and terminating the etching process at the cap layer 216, and then etching the cap layer 216. The etching process can be either a wet etching or a dry etching, as long as the etching selectivity is good. The drain electrode 233 is deposited on one end of the upper stacked cap layer 290, and an ohmic contact between the drain electrode 233 and the upper stacked cap layer 290 is formed. The source electrode 235 is deposited on another end of the upper stacked cap layer 290, and an ohmic contact between the source electrode 235 and the upper stacked cap layer 290 is formed.

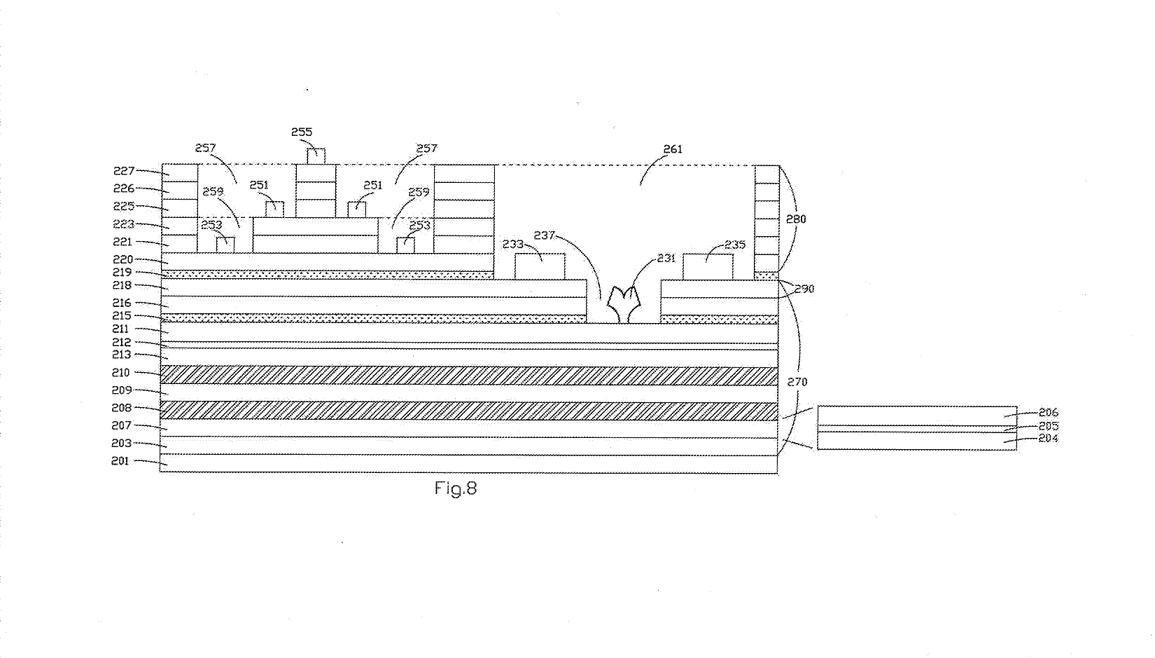

FIG. 8 is a sectional view of an embodiment of the improved pHEMT and HBT epitaxial structure in the present invention. The structure is mostly same to the embodiment shown in FIG. 7, except that an emitter contact layer 227 is further included on the emitter cap layer 226 positioning between the emitter cap layer 226 and the emitter electrode 255. The emitter contact layer 227 is made preferably of n-type doped AlGaAs doped with the preferable doping Si or similar materials. For the insertion of the emitter contact layer 227, the fabrication steps for the HBT and for the pHEMT should be modified accordingly. An additional step must be included in the fabrication steps of the HBT before etching the emitter cap layer 226 in the base electrode contact region 257, that is, first etching the emitter contact layer 227 in the base electrode contact region 257 and terminating the etching process at the emitter cap layer 226, and then etching the emitter cap layer 226 in the base electrode contact region 257 and forming an ohmic contact between the base electrode 255 and the emitter contact layer 227. An additional step must be included as well in the fabrication steps of the pHEMT before etching the HBT structure 280, that is, first etching the emitter contact layer 227 in the pHEMT etching region 261 and terminating the etching process at the emitter cap layer 226, and then etching the HBT structure 280 in the pHEMT etching region 261 sequentially.

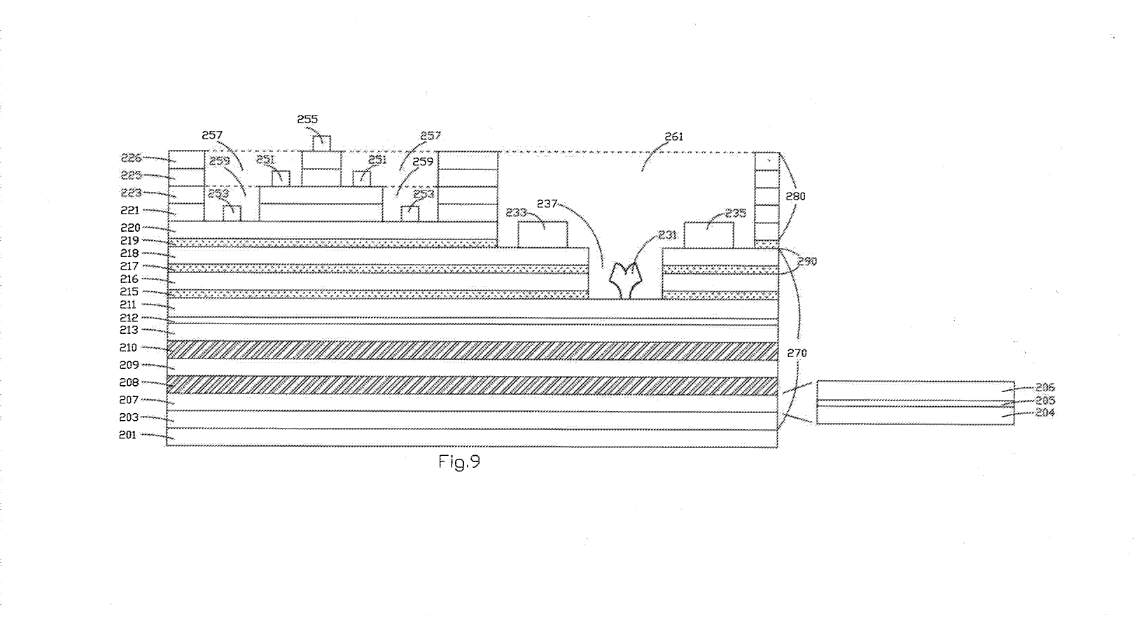

FIG. 9 is a sectional view of an embodiment of the improved pHEMT and HBT epitaxial structure in the present invention. The structure is mostly same to the embodiment shown in FIG. 7, except that a stacked etching-stop layer 217 is disposed in the structure of the upper stacked layer 290 below the stacked cap layer 218. The upper stacked cap layer 290 comprises a stacked cap layer 218 and a stacked etching-stop layer 217 below the stacked cap layer 218. The stacked etching-stop layer 217 is made of AlAs or InGaP. An additional step for etching the stacked etching-stop layer 217 must be included before etching the upper stacked cap layer 290. The etching process can be either a wet etching or a dry etching, as long as the etching selectivity is good.

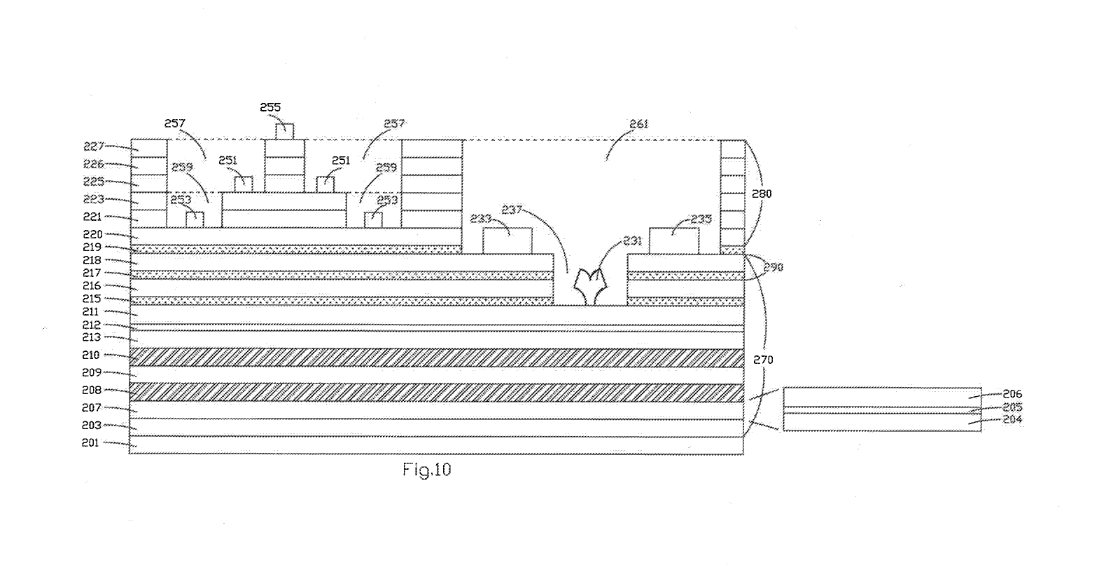

FIG. 10 is a sectional view of an embodiment of the improved pHEMT and HBT epitaxial structure in the present invention. The structure is mostly same to the embodiment shown in FIG. 9, except that an emitter contact layer 227 is further included on the emitter cap layer 226 positioning between the emitter cap layer 226 and the emitter electrode 255. The emitter contact layer 227 is made preferably of n-type doped AlGaAs doped with the preferable doping Si or similar materials. For the insertion of the emitter contact layer 227, the fabrication steps for the HBT and for the pHEMT should be modified accordingly. An additional step must be included in the fabrication steps of the HBT before etching the emitter cap layer 226 in the base electrode contact region 257, that is, first etching the emitter contact layer 227 in the base electrode contact region 257 and terminating the etching process at the emitter cap layer 226, and then etching the emitter cap layer 226 in the base electrode contact region 257 and forming an ohmic contact between the base electrode 255 and the emitter contact layer 227. An additional step must be included as well in the fabrication steps of the pHEMT before etching the HBT structure 280, that is, first etching the emitter contact layer 227 in the pHEMT etching region 261 and terminating the etching process at the emitter cap layer 226, and then etching the HBT structure 280 in the pHEMT etching region 261 sequentially.

To sum up, the present invention indeed can get its anticipatory object that is to provide an improved pHEMT and HBT integrated epitaxial structure, in which a first channel spacer layer and a second channel spacer layer are included above and below a channel layer respectively. The structure can disperse the electric field of the gate and lower the on-resistance significantly. When used in a switching device, the structure can provide the device with the advantage of the low insertion loss, the reduced device size, the stable fabrication process and high device reliability.

The description referred to the drawings stated above is only for the preferred embodiments of the present invention. Many equivalent local variations and modifications can still be made by those skilled at the field related with the present invention and do not depart from the spirits of the present invention, so they should be regarded to fall into the scope defined by the appended claims.

What is claimed is:

1. An improved pseudomorphic high electron mobility transistor (pHEMT) structure, comprising:
a substrate;
a buffer layer formed on said substrate;
a bottom barrier layer formed on said buffer layer;
a first channel spacer layer formed on said bottom barrier layer;
a channel layer formed on said first channel spacer layer, wherein said channel layer is composed of InₓGa₁₋ₓAs compound semiconductor with the Indium content 0.2<x<0.5;
a second channel spacer layer formed on said channel layer;
a Schottky spacer layer formed on said second channel spacer layer;
a Schottky donor layer formed on said Schottky spacer layer;
a Schottky barrier layer formed on said Schottky donor layer;
an etching-stop layer formed on said Schottky barrier layer;
at least one cap layer formed on said etching-stop layer;
a gate recess formed by using at least one etching process terminated at said Schottky barrier layer;
a gate electrode disposed in said gate recess on said Schottky barrier layer;
a drain electrode disposed on one end of said cap layer; and
a source electrode disposed on another end of said cap layer.

2. The improved pHEMT structure according to claim 1, wherein said bottom barrier layer comprises:
a barrier layer formed on said buffer layer;
a barrier donor layer formed on said barrier layer; and
a barrier spacer layer formed on said barrier donor layer, wherein said first channel spacer layer is formed on said barrier spacer layer.

3. The improved pHEMT structure according to claim 2, wherein said barrier layer, said barrier donor layer and said barrier spacer layer are composed of AlGaAs or GaAs.

4. The improved pHEMT structure according to claim 2, wherein said barrier donor layer and said Schottky donor layer are composed of a Si delta-doping.

5. The improved pHEMT structure according to claim 1, wherein the thickness of said channel layer is between 10 Å and 300 Å.

6. The improved pHEMT structure according to claim 1, wherein said first channel spacer layer and said second channel spacer layer are composed of GaAs.

7. The improved pHEMT structure according to claim 1, wherein the thickness of said first channel spacer layer and the thickness of said second channel spacer layer is between 10 Å and 200 Å.

8. The improved pHEMT structure according to claim 1, wherein said Schottky barrier layer, said Schottky donor layer and said Schottky spacer layer are composed of AlGaAs.

9. The improved pHEMT structure according to claim 1, wherein at least one upper stacked cap layer is disposed on said cap layer; said at least one upper stacked cap layer is positioned between said cap layer and said drain electrode and said at least one upper stacked cap layer is positioned between said cap layer and said source electrode; said at least one upper stacked cap layer includes at least one stacked cap layer.

10. The improved pHEMT structure according to claim 9, wherein a stacked etching-stop layer is further included in said upper stacked cap layer below said stacked cap layer, so that said upper stacked cap layer includes
said stacked etching-stop layer; and
said stacked cap layer disposed on said stacked etching-stop layer.

11. An improved pseudomorphic high electron mobility transistor (pHEMT) and heterojunction bipolar transistor (HBT) integrated epitaxial structure, comprising:
a substrate;
a pHEMT structure formed on said substrate;
an etching-stop spacer layer formed on said pHEMT structure; and
an HBT structure formed on said etching-stop spacer layer;
wherein said pHEMT structure comprises:
a buffer layer;
a bottom barrier layer formed on said buffer layer;
a first channel spacer layer formed on said bottom barrier layer;
a channel layer formed on said first channel spacer layer, wherein said channel layer is composed of InₓGa₁₋ₓAs compound semiconductor with the Indium content 0.2<x<0.5;
a second channel spacer layer formed on said channel layer;
a Schottky spacer layer formed on said second channel spacer layer;
a Schottky donor layer formed on said Schottky spacer layer;
a Schottky barrier layer formed on said Schottky donor layer;
an etching-stop layer formed on said Schottky barrier layer; and
at least one cap layer formed on said etching-stop layer;
and wherein said HBT structure comprises:
a sub-collector layer formed on said etching-stop spacer layer;
a collector layer formed on said sub-collector layer;
a base layer formed on said collector layer;
an emitter layer formed on said base layer; and
an emitter cap layer formed on said emitter layer.

12. The improved pHEMT and HBT integrated epitaxial structure according to claim 11, wherein said bottom barrier layer comprises:
a barrier layer formed on said buffer layer;
a barrier donor layer formed on said barrier layer; and
a barrier spacer layer formed on said barrier donor layer, wherein said first channel spacer layer is formed on said barrier spacer layer.

13. The improved pHEMT and HBT integrated epitaxial structure according to claim 12, wherein said barrier layer, barrier donor layer and said barrier spacer layer are composed of AlGaAs or GaAs.

14. The improved pHEMT and HBT integrated epitaxial structure according to claim 12, wherein said barrier donor layer and said Schottky donor layer are composed of a Si delta-doping.

15. The improved pHEMT and HBT integrated epitaxial structure according to claim 11, wherein the thickness of said channel layer is between 10 Å and 300 Å.

16. The improved pHEMT and HBT integrated epitaxial structure according to claim 11, wherein said first channel spacer layer and said second channel spacer layer are formed of GaAs.

17. The improved pHEMT and HBT integrated epitaxial structure according to claim 11, wherein the thickness of said first channel spacer layer and the thickness of said second channel spacer layer are between 10 Å and 200 Å.

18. The improved pHEMT and HBT integrated epitaxial structure according to claim 11, wherein said Schottky barrier layer, said Schottky donor layer and said Schottky spacer layer are composed of AlGaAs.

19. The improved pHEMT and HBT integrated epitaxial structure according to claim 11, wherein at least one upper stacked cap layer is disposed on said cap layer, and said upper stacked cap layer includes at least one stacked cap layer.

20. The improved pHEMT and HBT integrated epitaxial structure according to claim 19, wherein a stacked etching-stop layer is further included in said upper stacked cap layer below said stacked cap layer.
